(19) United States
(12) Patent Application Publication
(10) Pub. No.: US 2024/0254391 A1
(43) Pub. Date: Aug. 1, 2024

(54) WET ETCH FORMULATIONS AND RELATED METHODS

(71) Applicant: ENTEGRIS, INC., Billerica, MA (US)

(72) Inventors: Hunter Patrick Hickox, Bronx, NY (US); Atanu K. Das, Southbury, CT (US); Chia-Jung Hsu, Hsinchu City (TW); Steven A. Lippy, Brookfield, CT (US)

(21) Appl. No.: 18/430,567

(22) Filed: Feb. 1, 2024

Related U.S. Application Data
(60) Provisional application No. 63/442,582, filed on Feb. 1, 2023.

(51) Int. Cl. C09K 13/06; C23F 1/26

(52) U.S. Cl. CPC C09K 13/06; C23F 1/26

(57) ABSTRACT

Wet etch compositions and related methods are provided herein. A wet etch composition for molybdenum, may include phosphoric acid, acetic acid, nitric acid, and an additive for reducing an oxidation rate of a MoOₓ layer. The additive may be present in an amount of 0.01% to 5% by weight based on a total weight of the wet etch composition.

### FIELD

The present disclosure relates to the field of wet etch formulations and related methods.

### BACKGROUND

3D NAND structures include layers of molybdenum that must be selectively removed via etching. Removing the molybdenum in the recesses of the 3D NAND structures without removing non-molybdenum materials, such as tetraethyl orthosilicate (TEOS) and aluminum oxide, remains an ongoing challenge. Another ongoing challenge is the lack of uniformity in etch depth resulting in etched molybdenum layers of varying depths.

### SUMMARY

Some embodiments relate to a wet etch composition for a molybdenum material. In some embodiments, the wet etch composition comprises at least one of phosphoric acid, acetic acid, nitric acid, an additive for reducing an oxidation rate of a MoOₓ layer, or any combination thereof. In some embodiments, the additive is present in an amount of 0.01% to 5% by weight based on a total weight of the wet etch composition.

Some embodiments relate to a method for etching a molybdenum material. In some embodiments, the method comprises one or more of the following steps: obtaining a structure comprising a plurality of recesses, and a molybdenum material disposed in the plurality of recesses; and contacting the structure with a wet etch composition to remove at least a portion of the molybdenum material. In some embodiments, the wet etch composition comprises at least one of phosphoric acid, acetic acid, nitric acid, an additive for reducing an oxidation rate of a MoOₓ layer, or any combination thereof. In some embodiments, the additive is present in an amount of 0.01% to 5% by weight based on a total weight of the wet etch composition.

### BRIEF DESCRIPTION OF DRAWINGS

Some embodiments of the disclosure are herein described, by way of example only, with reference to the accompanying drawings. With specific reference now to the drawings in detail, it is stressed that the embodiments shown are by way of example and for purposes of illustrative discussion of embodiments of the disclosure. In this regard, the description taken with the drawings makes apparent to those skilled in the art how embodiments of the disclosure may be practiced.

FIG. 1 presents an illustration of a process flow showing a 3D NAND structure with tetraethyl orthosilicate (TEOS), aluminum oxide, and molybdenum, according to some embodiments.

FIG. 2 presents an illustration of the results of a method for the removal of molybdenum, where a 3D NAND structure with molybdenum is subjected to a wet etch composition, according to some embodiments.

FIG. 3 presents a flow chart of a method for the removal of molybdenum, where a 3D NAND structure with molybdenum is subjected to a wet etch composition, according to some embodiments.

### DETAILED DESCRIPTION

Among those benefits and improvements that have been disclosed, other objects and advantages of this disclosure will become apparent from the following description taken in conjunction with the accompanying figures. Detailed embodiments of the present disclosure are disclosed herein; however, it is to be understood that the disclosed embodiments are merely illustrative of the disclosure that may be embodied in various forms. In addition, each of the examples given regarding the various embodiments of the disclosure which are intended to be illustrative, and not restrictive.

Any prior patents and publications referenced herein are incorporated by reference in their entireties.

Throughout the specification and claims, the following terms take the meanings explicitly associated herein, unless the context clearly dictates otherwise. The phrases “in one embodiment,” “in an embodiment,” and “in some embodiments” as used herein do not necessarily refer to the same embodiment(s), though it may. Furthermore, the phrases “in another embodiment” and “in some other embodiments” as used herein do not necessarily refer to a different embodiment, although it may. All embodiments of the disclosure are intended to be combinable without departing from the scope or spirit of the disclosure.

As used herein, the term “based on” is not exclusive and allows for being based on additional factors not described, unless the context clearly dictates otherwise. In addition, throughout the specification, the meaning of “a,” “an,” and “the” include plural references. The meaning of “in” includes “in” and “on.”

Some embodiments relate to wet etch formulations and related methods for selective removal of a molybdenum material from a microelectronic device, such as, for example and without limitation, a 3D NAND structure. The selective removal of molybdenum can improve the recess depth uniformity across the 3D NAND structure to maintain yield and prevent variations in chemical compositions and electrical performance. In some embodiments, a wet etch composition may include phosphoric acid (H₃PO₄), acetic acid (CH₃COOH), nitric acid (HNO₃), and an additive for reducing the oxidation rate of a molybdenum oxide (MoOₓ) layer. In some embodiments, the additive may be present in an amount of 0.01% to 5% by weight based on a total weight of the wet etch composition. In some embodiments, the x of the MoOₓ (molybdenum oxide) layer is 1 to 5.

The additive of the wet etch composition may be at least one of a nitrogen-containing salt, a nitrogen-containing acid, a nitrogen-containing compound, a phosphorus-containing acid, a phosphorus-containing oxide, and a phosphorus-containing salt, or any combination thereof. In some embodiments, the wet etch composition may be at least one of an ammonium salt, an organic chloride salt, a phosphonic acid, a phosphine oxide, an ammonium salt of phosphoric acid, a benzotriazole, and citric acid, a quaternary ammonium salt or any combination thereof. In some embodiments, a quaternary ammonium salt comprises a nitrogen-containing salt having four (4) bonds. In some embodiments, the additive may be at least one of, benzyldimethyldodecylammonium chloride, 1-dodecylpyridinium chloride, 1-methyl-3-N-octylimidazolium chloride, 1-methyl-3-N-octylimidazolium chloride, and 1-decyl-3-methylimidazolium chloride, or any combination thereof. In some embodiments, the additive may be at least one of n-dodecylphosphonic acid and benzylphosphonic acid, or any combination thereof. In some embodiments, the additive may be at least one of trioctylphosphine oxide, triphenylphosphine oxide, triphenylphosphine oxide, triethylamine phosphate, ammonium phosphate monobasic, and 5-methyl-1H-benzotriazole or any combination thereof.

The wet etch composition may be 1% to 20% by weight of phosphoric acid based on the total weight of the wet etch composition, or any range or subrange between 1% to 20%. For example, in some embodiments, the percent by weight of phosphoric acid based on the total weight of the wet etch composition may be 1% to 15%, 1% to 10%, or 5% to 20%. In some embodiments, the percent by weight of phosphoric acid based on the total weight of the wet etch composition may be 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%. In some embodiments, the percent by weight of phosphoric acid based on the total weight of the wet etch composition may be 1% to 19%, 1% to 18%, 1% to 17%, 1% to 16%, 1% to 15%, 1% to 14%, 1% to 13%, 1% to 12%, 1% to 11%, 1% to 10%, 1% to 9%, 1% to 8%, 1% to 7%, 1% to 6%, 1% to 5%, 1% to 4%, 1% to 3%, or 1% to 2%.

The wet etch composition may be 50% to 90% by weight of acetic acid based on the total weight of the wet etch composition, or any range or subrange between 50% and 90%. For example, in some embodiments, the percent by weight of acetic acid based on the total weight of the wet etch composition may be 55% to 90%, 60% to 90%, 65% to 90%, 70% to 90%, 75% to 90%, 80% to 90%, or 85% to 90%. In some embodiments, the percent by weight of acetic acid based on the total weight of the wet etch composition may be 51% to 90%, 52% to 90%, 53% to 90%, 54% to 90%, 55% to 90%, 56% to 90%, 57% to 90%, 58% to 90%, 59% to 90%, 60% to 90%, 61% to 90%, 62% to 90%, 63% to 90%, 64% to 90%, 65% to 90%, 66% to 90%, 67% to 90%, 68% to 90%, 69% to 90%, 70% to 90%, 71% to 90%, 72% to 90%, 73% to 90%, 74% to 90%, 75% to 90%, 76% to 90%, 77% to 90%, 78% to 90%, 79% to 90%, 80% to 90%, 80% to 95%, 81% to 90%, 82% to 90%, 83% to 90%, 84% to 90%, 85% to 90%, 86% to 90%, 87% to 90%, 88% to 90%, or 89% to 90%. In some embodiments, the percent by weight of acetic acid based on the total weight of the wet etch composition may 50% to 89%, 50% to 88%, 50% to 87%, 50% to 86%, 50% to 85%, 50% to 84%, 50% to 83%, 50% to 82%, 50% to 81%, 50% to 80%, 50% to 79%, 50% to 78%, 50% to 77%, 50% to 76%, 50% to 75%, 50% to 74%, 50% to 73%, 50% to 72%, 50% to 71%, 50% to 70%, 50% to 69%, 50% to 68%, 50% to 67%, 50% to 66%, 50% to 65%, 50% to 64%, 50% to 63%, 50% to 62%, 50% to 61%, 50% to 60%, 50% to 59%, 50% to 58%, 50% to 57%, 50% to 56%, 50% to 55%, 50% to 54%, 50% to 53%, 50% to 52%, or 50% to 51%.

The wet etch composition may be 0.1% to 20% by weight of nitric acid based on the total weight of the wet etch composition, or any range or subrange between 0.1% and 20%. For example, in some embodiments, the percent by weight of nitric acid based on the total weight of the wet etch composition may be 1% to 20%, 1% to 15%, 1% to 10%, or 5% to 20%. In some embodiments, the percent by weight of nitric acid based on the total weight of the wet etch composition may be 1% to 20%, 2% to 20%, 3% to 20%, 4% to 20%, 5% to 20%, 6% to 20%, 7% to 20%, 8% to 20%, 9% to 20%, 10% to 20%, 11% to 20%, 12% to 20%, 13% to 20%, 14% to 20%, 15% to 20%, 16% to 20%, 17% to 20%, 18% to 20%, or 19% to 20%. In some embodiments, the percent by weight of nitric acid based on the total weight of the wet etch composition may be 0.1% to 19%, 0.1% to 18%, 0.1% to 17%, 0.1% to 16%, 0.1% to 15%, 0.1% to 14%, 0.1% to 13%, 0.1% to 12%, 0.1% to 11%, 0.1% to 10%, 0.1% to 9%, 0.1% to 8%, 0.1% to 7%, 0.1% to 6%, 0.1% to 5%, 0.1% to 4%, 0.1% to 3%, 0.1% to 2%, or 0.1% to 1%. In some embodiments, the percent by weight of nitric acid based on the total weight of the wet etch composition may be 0.1% to 5%, 0.5% to 5%, 1% to 5%, 1.5% to 5%, 2% to 5%, 2.5% to 5%, 3% to 5%, 3.5% to 5%, 4% to 5%, or 4.5% to 5%. In some embodiments, the percent by weight of nitric acid based on the total weight of the wet etch composition may be 0.1% to 5%, 0.1% to 4.5%, 0.1% to 4%, 0.1% to 3.5%, 0.1% to 3%, 0.1% to 2.5%, 0.1% to 2%, 0.1% to 1.5%, 0.1% to 1%, or 0.1% to 0.5%.

The wet etch composition may further include be 0.1% to 10% by weight of citric acid based on the total weight of the wet etch composition, or any range or subrange between 0.1% and 10%. For example, in some embodiments, the percent by weight of citric acid based on the total weight of the wet etch composition may be 0.1% to 10%, 1% to 5%, 1% to 2.5%, or 2.5% to 5%. In some embodiments, the percent by weight of citric acid based on the total weight of the wet etch composition may be 0.1% to 5%, 0.5% to 5%, 1% to 5%, 1.5% to 5%, 2% to 5%, 2.5% to 5%, 3% to 5%, 3.5% to 5%, 4% to 5%, or 4.5% to 5%. In some embodiments, the percent by weight of citric acid based on the total weight of the wet etch composition may be 0.1% to 5%, 0.1% to 4.5%, 0.1% to 4%, 0.1% to 3.5%, 0.1% to 3%, 0.1% to 2.5%, 0.1% to 2%, 0.1% to 1.5%, 0.1% to 1%, or 0.1% to 0.5%.

The wet etch composition may not comprise a tungsten compound. In some embodiments, the tungsten compound comprises at least one of tungsten oxide, tungsten trioxide, tungstic acid, sodium tungstate, ammonium paratungstate, tungsten carbide, and ditungsten carbide, or any combination thereof.

Some embodiments relate to wet etch formulations and related methods for selectively removing molybdenum from a 3D NAND structure. In some embodiments, a method may include obtaining a structure comprising a plurality of recesses and a molybdenum material disposed in the plurality of recesses and contacting the structure with a wet etch composition to remove at least a portion of the molybdenum material. In some embodiments, the structure may have a plurality of recesses and a molybdenum material disposed in the plurality of recesses. In some embodiments, the wet etch composition may include phosphoric acid, acetic acid, nitric acid, and an additive for reducing the oxidation rate of a MoOₓ layer. In some embodiments, the additive may be present in an amount of 0.01% to 5% by weight based on a total weight of the wet etch composition. In some embodiments, the x of the MoOₓ (molybdenum oxide) layer is 1 to 5.

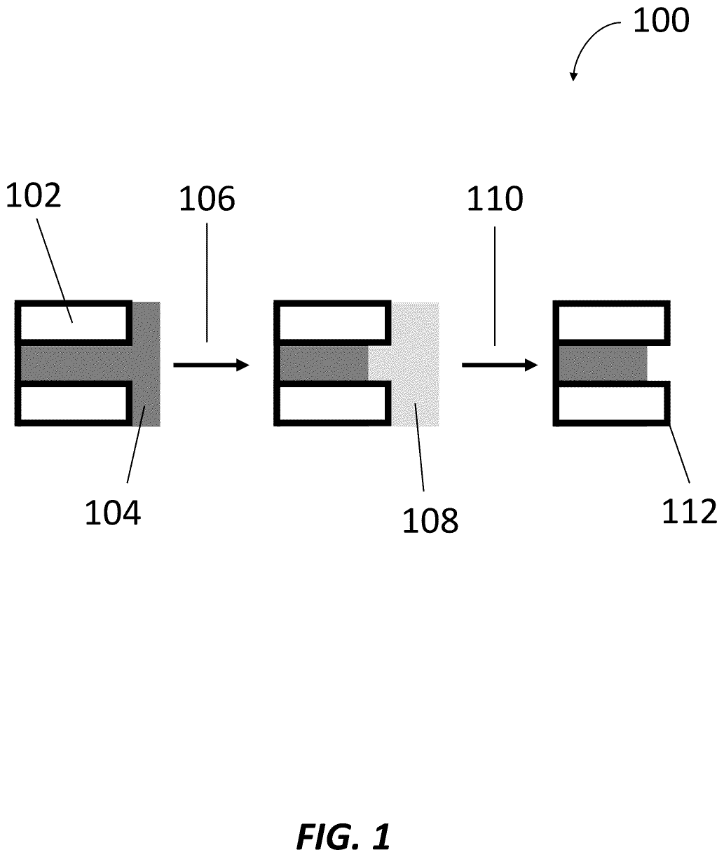

FIG. 1 presents an illustration of a process flow 100 showing a 3D NAND structure with tetraethyl orthosilicate (TEOS) 102, aluminum oxide 112, and molybdenum 104. The first step of the molybdenum 104 removal may be oxidation 106 of the molybdenum 104 to create a molybdenum oxide layer 108. After oxidation 106, the molybdenum oxide layer 108 may undergo etching 110. After etching 110, the recesses of the 3D NAND structure may be uniform.

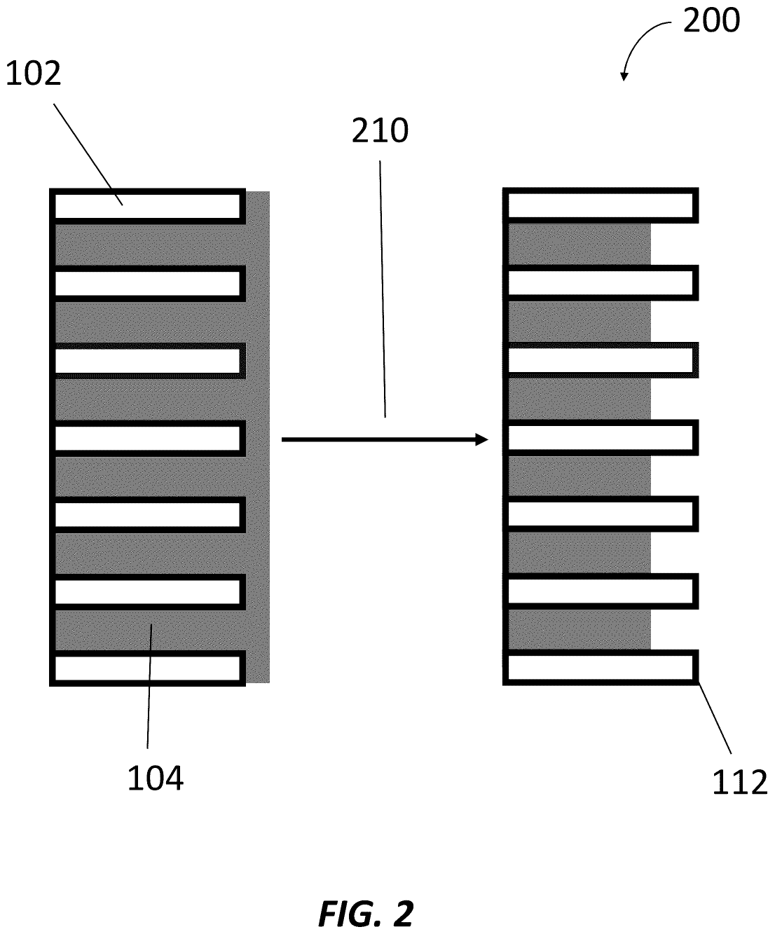

FIG. 2 presents an illustration of the results 200 of a method for the removal of molybdenum 104. As shown in FIGS. 1-3, a 3D NAND structure with molybdenum 104 is subjected to a wet etch composition 210. In some embodiments, the wet etch composition 210 is a PAN composition (phosphoric acid, acetic acid, and nitric acid). In some embodiments, the PAN composition may include an additive for reducing the oxidation rate of a molybdenum oxide layer 108. In some embodiments, the additive may be present in an amount of 0.01% to 5% by weight based on a total weight of the wet etch composition 210.

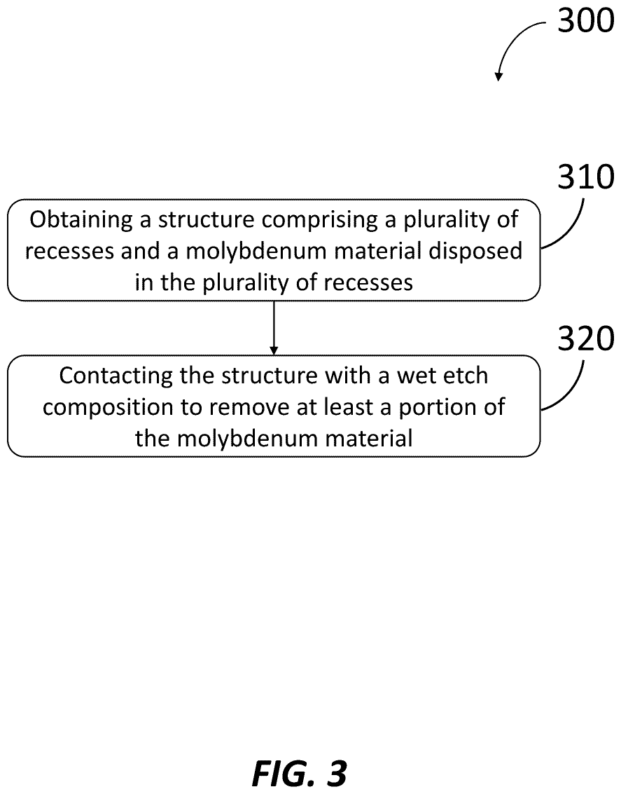

FIG. 3 presents a flow chart of a method 300 for the removal of molybdenum. As shown in FIGS. 1-3, a 3D NAND structure with molybdenum 104 is subjected to a wet etch composition 210. In some embodiments, the method 300 may be obtaining a structure comprising a plurality of recesses and a molybdenum material disposed in the plurality of recesses 310 and contacting the structure with a wet etch composition to remove at least a portion of the molybdenum material 320. In some embodiments, the structure may be a 3D NAND structure. In some embodiments, the wet etch composition 210 may be phosphoric acid, acetic acid, nitric acid, and an additive for reducing the oxidation rate of a molybdenum oxide layer. In some embodiments, the additive may be present in an amount of 0.01% to 5% by weight based on a total weight of the wet etch composition.

### Example 1

Various wet etch compositions were prepared and the performance of each was compared to a control composition. All samples were prepared with the following order of addition: nitric acid, glacial acetic acid, phosphoric acid, water, and additive(s).

Sample A is a wet etch composition comprising 1% to 15% by weight of phosphoric acid, 80% to 95% by weight of acetic acid, 0.1% to 5% by weight of nitric acid, 1% to 10% by weight of water, and 1% by weight of benzyldimethyldodecylammonium chloride. Sample B is a wet etch composition comprising 1% to 15% by weight of phosphoric acid, 80% to 95% by weight of acetic acid, 0.1% to 5% by weight of nitric acid, 1% to 10% by weight of water, and 0.05% by weight of 1-dodecylpyridinium chloride. Sample C is a wet etch composition comprising 1% to 15% by weight of phosphoric acid, 80% to 95% by weight of acetic acid, 0.1% to 5% by weight of nitric acid, 1% to 10% by weight of water, and 0.05% by weight of 1-methyl-3-N-octylimidazolium chloride. Sample D is a wet etch composition comprising 1% to 15% by weight of phosphoric acid, 80% to 95% by weight of acetic acid, 0.1% to 5% by weight of nitric acid, 1% to 10% by weight of water, 0.01% to 5% by weight of 1-dodecylpyridinium chloride, and 0.01% to 5% by weight of citric acid.

The control composition included 1% to 15% by weight of phosphoric acid, 80% to 95% by weight of acetic acid, 0.1% to 5% by weight of nitric acid, 1% to 10% by weight of water, and no additive. All weight percentages are based on a total weight of the composition, unless otherwise provided herein.

Each of the compositions were applied to a structure comprising a plurality of recesses, and a molybdenum material disposed in the plurality of recesses, at room temperature for a contact period. After the contact period, the average depth of the molybdenum material in a top portion, a middle portion, and a bottom portion of the structure was measured and is reported in Table 1 below.

TABLE 1
Wet Etch Composition Performance

| | | Recess |
|---|---|---|
| | | Uniformity |
| | Process | Improvement |
| Formulation | Conditions | (%) |
| Control | R.T/3.5 min | — |
| Sample A | R.T./6 min | 87.9 |
| Sample B | R.T/3.5 min | 90.9 |
| Sample C | R.T/3.5 min | 84.8 |

As shown, the addition of a small amount of additive to each of the wet etch compositions markedly improved the difference in average recess depth of the molybdenum material—i.e., improved recess depth uniformity—relative to the control composition.

### Aspects

Various Aspects are described below. It is to be understood that any one or more of the features recited in the following Aspect(s) can be combined with any one or more other Aspect(s).

Aspect 1. A wet etch composition for molybdenum, comprising:
phosphoric acid;
acetic acid;
nitric acid; and
an additive for reducing an oxidation rate of a MoOₓ layer,
   wherein the additive is present in an amount of 0.01% to 5% by weight based on a total weight of the wet etch composition.

Aspect 2. The wet etch composition according to Aspect 1, wherein the additive comprises at least one of an ammonium salt, an organic chloride salt, a phosphonic acid, a phosphine oxide, an ammonium salt of phosphoric acid, a benzotriazole, and citric acid, or any combination thereof.

Aspect 3. The wet etch composition according to any one of Aspects 1-2, wherein the additive comprises at least one of benzyldimethyldodecylammonium chloride, 1-dodecylpyridinium chloride, 1-methyl-3-N-octylimidazolium chloride, 1-methyl-3-N-octylimidazolium chloride, and 1-decyl-3-methylimidazolium chloride, or any combination thereof.

Aspect 4. The wet etch composition according to any one of Aspects 1-3, wherein the additive comprises at least one of n-dodecylphosphonic acid and benzylphosphonic acid, or any combination thereof.

Aspect 5. The wet etch composition according to any one of Aspects 1-4, wherein the additive comprises at least one of trioctylphosphine oxide, triphenylphosphine oxide, triphenylphosphine oxide, triethylamine phosphate, ammonium phosphate monobasic, and 5-methyl-1H-benzotriazole or any combination thereof.

Aspect 6. The wet etch composition according to any one of Aspects 1-5, wherein the wet etch composition comprises 1% to 20% by weight of phosphoric acid based on the total weight of the wet etch composition.

Aspect 7. The wet etch composition according to any one of Aspects 1-6, wherein the wet etch composition comprises 50% to 90% by weight of acetic acid based on the total weight of the wet etch composition.

Aspect 8. The wet etch composition according to any one of Aspects 1-7, wherein the wet etch composition comprises 0.1% to 20% by weight of nitric acid based on the total weight of the wet etch composition.

Aspect 9. The wet etch composition according to any one of Aspects 1-8, wherein the wet etch composition does not comprise a tungsten compound.

Aspect 10. The wet etch composition according to any one of Aspects 1-9, wherein x of the MoOₓ layer is 1 to 5.

Aspect 11. A method, comprising:
obtaining a structure comprising a plurality of recesses, and a molybdenum material disposed in the plurality of recesses; and
contacting the structure with a wet etch composition to remove at least a portion of the molybdenum material,
   wherein the wet etch composition comprises:
      phosphoric acid;
      acetic acid;
      nitric acid; and
      an additive for reducing an oxidation rate of a MoOₓ layer,
         wherein the additive is present in an amount of 0.01% to 5% by weight based on a total weight of the wet etch composition.

Aspect 12. The method according to Aspect 11, wherein the additive comprises at least one of an ammonium salt, an organic chloride salt, a phosphonic acid, a phosphine oxide, an ammonium salt of phosphoric acid, a benzotriazole, and citric acid, or any combination thereof.

Aspect 13. The method according to any one of Aspects 11-12, wherein the additive comprises at least one of benzyldimethyldodecylammonium chloride, 1-dodecylpyridinium chloride, 1-methyl-3-N-octylimidazolium chloride, 1-methyl-3-N-octylimidazolium chloride, and 1-decyl-3-methylimidazolium chloride, or any combination thereof.

Aspect 14. The method according to any one of Aspects 11-13, wherein the additive comprises at least one n-dodecylphosphonic acid and benzylphosphonic acid, or any combination thereof.

Aspect 15. The method according to any one of Aspects 11-14, wherein the additive comprises at least one of trioctylphosphine oxide, triphenylphosphine oxide, triphenylphosphine oxide, triethylamine phosphate, ammonium phosphate monobasic, and 5-methyl-1H-benzotriazole or any combination thereof.

Aspect 16. The method according to any one of Aspects 11-15, wherein the wet etch composition comprises 1% to 20% by weight of phosphoric acid based on the total weight of the wet etch composition.

Aspect 17. The method according to any one of Aspects 11-16, wherein the wet etch composition comprises 50% to 90% by weight of acetic acid based on the total weight of the wet etch composition.

Aspect 18. The method according to any one of Aspects 11-17, wherein the wet etch composition comprises 0.1% to 20% by weight of nitric acid based on the total weight of the wet etch composition.

Aspect 19. The method according to any one of Aspects 11-18, wherein the wet etch composition does not comprise a tungsten compound. s

Aspect 20. The method according to any one of Aspects 11-19, wherein x of the MoOₓ layer is 1 to 5.

It is to be understood that changes may be made in detail, especially in matters of the construction materials employed and the shape, size, and arrangement of parts without departing from the scope of the present disclosure. This Specification and the embodiments described are examples, with the true scope and spirit of the disclosure being indicated by the claims that follow.

What is claimed is:

1. A wet etch composition for molybdenum, comprising:
phosphoric acid;
acetic acid;
nitric acid; and
an additive for reducing an oxidation rate of a MoOₓ layer,
wherein the additive is present in an amount of 0.01% to 5% by weight based on a total weight of the wet etch composition.

2. The wet etch composition of claim 1, wherein the additive comprises at least one of an ammonium salt, an organic chloride salt, a phosphonic acid, a phosphine oxide, an ammonium salt of phosphoric acid, a benzotriazole, and citric acid, or any combination thereof.

3. The wet etch composition of claim 1, wherein the additive comprises at least one of benzyldimethyldodecylammonium chloride, 1-dodecylpyridinium chloride, 1-methyl-3-N-octylimidazolium chloride, 1-methyl-3-N-octylimidazolium chloride, and 1-decyl-3-methylimidazolium chloride, or any combination thereof.

4. The wet etch composition of claim 1, wherein the additive comprises at least one of n-dodecylphosphonic acid and benzylphosphonic acid, or any combination thereof.

5. The wet etch composition of claim 1, wherein the additive comprises at least one of trioctylphosphine oxide, triphenylphosphine oxide, triphenylphosphine oxide, triethylamine phosphate, ammonium phosphate monobasic, and 5-methyl-1H-benzotriazole or any combination thereof.

6. The wet etch composition of claim 1, wherein the wet etch composition comprises 1% to 20% by weight of phosphoric acid based on the total weight of the wet etch composition.

7. The wet etch composition of claim 1, wherein the wet etch composition comprises 50% to 90% by weight of acetic acid based on the total weight of the wet etch composition.

8. The wet etch composition of claim 1, wherein the wet etch composition comprises 0.1% to 20% by weight of nitric acid based on the total weight of the wet etch composition.

9. The wet etch composition of claim 1, wherein the wet etch composition does not comprise a tungsten compound.

10. The wet etch composition of claim 1, wherein x of the MoOₓ layer is 1 to 5.

11. A method, comprising:
obtaining a structure comprising a plurality of recesses, and a molybdenum material disposed in the plurality of recesses; and
contacting the structure with a wet etch composition to remove at least a portion of the molybdenum material,
wherein the wet etch composition comprises:
phosphoric acid;
acetic acid;
nitric acid; and
an additive for reducing an oxidation rate of a MoOₓ layer,
wherein the additive is present in an amount of 0.01% to 5% by weight based on a total weight of the wet etch composition.

12. The method of claim 11, wherein the additive comprises at least one of an ammonium salt, an organic chloride salt, a phosphonic acid, a phosphine oxide, an ammonium salt of phosphoric acid, a benzotriazole, and citric acid, or any combination thereof.

13. The method of claim 11, wherein the additive comprises at least one of benzyldimethyldodecylammonium chloride, 1-dodecylpyridinium chloride, 1-methyl-3-N-octylimidazolium chloride, 1-methyl-3-N-octylimidazolium chloride, and 1-decyl-3-methylimidazolium chloride, or any combination thereof.

14. The method of claim 11, wherein the additive comprises at least one n-dodecylphosphonic acid and benzylphosphonic acid, or any combination thereof.

15. The method of claim 11, wherein the additive comprises at least one of trioctylphosphine oxide, triphenylphosphine oxide, triphenylphosphine oxide, triethylamine phosphate, ammonium phosphate monobasic, and 5-methyl-1H-benzotriazole or any combination thereof.

16. The method of claim 11, wherein the wet etch composition comprises 1% to 20% by weight of phosphoric acid based on the total weight of the wet etch composition.

17. The method of claim 11, wherein the wet etch composition comprises 50% to 90% by weight of acetic acid based on the total weight of the wet etch composition.

18. The method of claim 11, wherein the wet etch composition comprises 0.1% to 20% by weight of nitric acid based on the total weight of the wet etch composition.

19. The method of claim 11, wherein the wet etch composition does not comprise a tungsten compound.

20. The method of claim 11, wherein x of the MoOₓ layer is 1 to 5.
